(19) United States
(12) Patent Application Publication
(10) Pub. No.: US 2025/0248152 A1
(43) Pub. Date: Jul. 31, 2025

(54) ELECTRONIC DEVICES AND METHODS OF MANUFACTURING ELECTRONIC DEVICES

(71) Applicant: Amkor Technology Singapore Holding Pte. Ltd., Singapore (SG)

(72) Inventors: Weilung Lu, Tempe, AZ (US); Adrian Arcedera, Chandler, AZ (US); Tobias Schramm, Pierre-Benite (FR); David Clark, Suffolk (GB); Stefan Martens, Munchen (DE)

(73) Assignee: Amkor Technology Singapore Holding Pte. Ltd., Singapore (SG)

(21) Appl. No.: 18/825,261

(22) Filed: Sep. 5, 2024

Related U.S. Application Data
(60) Provisional application No. 63/627,302, filed on Jan. 31, 2024.

(51) Int. Cl. H01L 27/146

(52) U.S. Cl. CPC H10F 39/804; H10F 39/026

(57) ABSTRACT

In one example, an electronic device comprises a substrate comprising a dielectric structure and a conductive structure, a first electronic component over a top side of the substrate and comprising a first transceiver, wherein the first electronic component is coupled to the conductive structure, a second electronic component coupled to the substrate and the conductive structure and comprising a second transceiver, an encapsulant over the top side of the substrate and defining a cavity, wherein the second transceiver is in the cavity and the first electronic component is covered by the encapsulant, and a lid over the top side of the substrate and covering the second electronic component. Other examples and related methods are also disclosed herein.

### CROSS-REFERENCE TO RELATED APPLICATIONS

The present application claims the benefit of U.S. Provisional Application No. 63/627,302 filed Jan. 31, 2024. Said Application No. 63/627,302 is hereby incorporated herein by reference in its entirety.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2F show cross-sectional views of an example method for manufacturing an example electronic device.

FIG. 3 shows a cross-sectional view of an example electronic device.

FIG. 4 shows a cross-sectional view of an example electronic device.

FIGS. 5A to 5H show cross-sectional views of an example method for manufacturing an example electronic device.

FIGS. 6A to 6B show cross-sectional views of example electronic devices.

FIG. 7 shows a cross-sectional view of an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.,” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprise”, “comprises”, “comprising”, “include”, “includes”, and “including” are “open ended” terms and specify the presence of stated features, but do not preclude the presence or addition of one or more other features. The terms “first”, “second”, “third”, and so on can be used herein to describe various elements; however, the described elements shall not be limited by these terms. The terms first, second third, etc. are only used to distinguish one element from another. Thus, for example, a first element discussed in the present disclosure could be termed a second element without departing from the teachings of the present disclosure.

Unless specified otherwise, the term “coupled” can be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” can be used to describe two elements directly contacting each other or describe two elements indirectly coupled by one or more other elements. As used herein, the term “coupled” can refer to an electrical or mechanical coupling.

### DESCRIPTION

In one example, an electronic device comprises a substrate comprising a dielectric structure and a conductive structure, a first electronic component over a top side of the substrate and comprising a first transceiver, wherein the first electronic component is coupled to the conductive structure, a second electronic component coupled to the substrate and the conductive structure and comprising a second transceiver, an encapsulant over the top side of the substrate and defining a cavity, wherein the second transceiver is in the cavity and the first electronic component is covered by the encapsulant, and a lid over the top side of the substrate and covering the second electronic component.

In another example, an electronic device comprises a substrate comprising a dielectric structure and a conductive structure, a first electronic component coupled to the substrate and the conductive structure and comprising a first transceiver, a second electronic component coupled to the substrate and the conductive structure and comprising a second transceiver, an encapsulant over the substrate and the first electronic component and defining a cavity, wherein the cavity is coincident with the second transceiver, and a lid over the second electronic component.

In a further example, a method to manufacture an electronic device comprises providing a substrate comprising a dielectric structure and a conductive structure, providing a first electronic component over a top side of the substrate and comprising a first transceiver, wherein the first electronic component is coupled to the conductive structure, providing an encapsulant over the top side of the substrate and defining a cavity, wherein the first electronic component is covered by the encapsulant, providing a second electronic component coupled to the conductive structure in the cavity and comprising a second transceiver, and providing a lid over the top side of the substrate and covering the second electronic component.

Other examples are included in the present disclosure. Such examples may be found in the figures, in the claims, or in the description of the present disclosure.

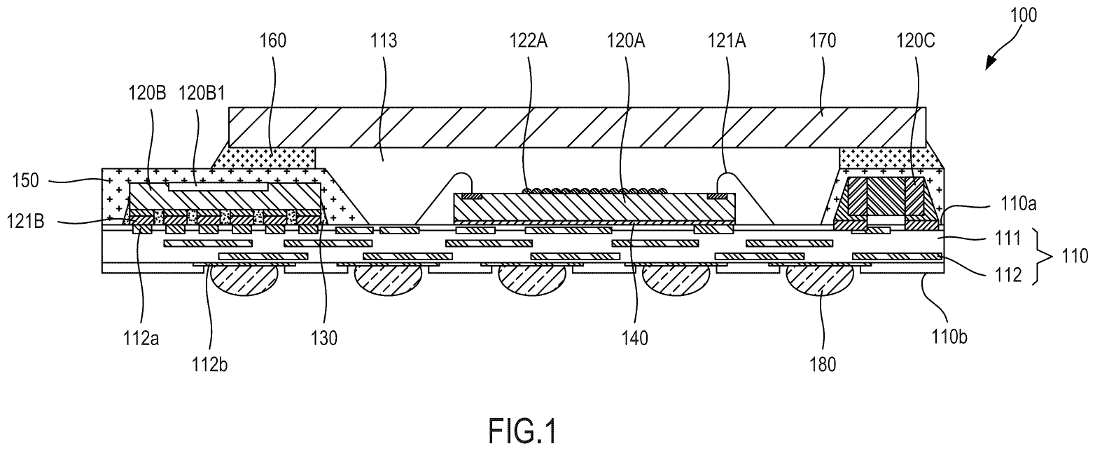

FIG. 1 shows a cross-sectional view of an example electronic device 100. In the example shown in FIG. 1, electronic device 100 can comprise substrate 110, electronic component 120A, electronic component 120B, and electronic component 120C. Substrate 110 can comprise dielectric structure 111 and conductive structure 112 and can comprise substrate top side 110a and substrate bottom side 110b. Electronic component 120A can be over top side 110a of substrate 110 and coupled to conductive structure 112. Die attach material 140 can be between electronic component 120A and top side 110a of substrate 110. Electronic component 120B can be over top side 110a of substrate 110 and coupled to conductive structure 112. Underfill 130 can be between electronic component 120B and top side 110a of substrate 110. In some examples, conductive structure 112 can comprise one or more substrate inward terminals 112a at top side 110a of substrate 112. One or more component interconnects 121B can couple electronic component 120B to one or more substrate inward terminals 112a. Electronic component 120C can be over top side 110a of substrate 110 and can be coupled to conductive structure 112.

Encapsulant 150 can be over top side 110a of substrate 110 and can cover lateral sides of electronic component 120B and electronic component 120C. In some examples, encapsulant 150 can cover the top side of electronic component 120B or the top side of electronic component 120C. In some examples, a top side of encapsulant 150 can be coplanar with the top side of electronic component 120B or the top side of electronic component 120C In some examples, encapsulant 150 can define cavity 113 over top side 110a of substrate 110, and electronic component 120A can be disposed in cavity 113. Transceiver 122A of electronic component 120A can be exposed from cavity 113, for example where electronic component 120A is in cavity 113 or below cavity 113. In some examples, a footprint of transceiver 122A can be coincident or overlap a footprint of cavity 113 wherein transceiver 122A is exposed from cavity 113. Electronic component 120A can be coupled to conductive structure 112 via one or more component interconnects 121A. For example, one or more component interconnects 121A can couple electronic component 120A to one or more substrate inward terminals 112a. Electronic component 120A can have transceiver 122A or sensing area in or on a top side of electronic component 120A. Electronic component 120B can have transceiver 120B1 or sensing area in or on a top side of electronic component 120B. Lid 170 can be disposed over substrate 110 and over electronic component 120A and encapsulant 150. Lid 170 can be coupled to encapsulant 150 via lid attach material 160. In some examples, lid attach material 160 can seal lid 170 to encapsulant 150 to hermetically seal cavity 113 from the external environment. In some examples, one or more external interconnects 180 can be coupled to conductive structure 112 at bottom side 110b of substrate 110. In some examples, conductive structure 112 can comprise one or more substrate outward terminals 112b at bottom side 110b of substrate 110, and external interconnects 180 can be coupled to substrate outward terminals 112b.

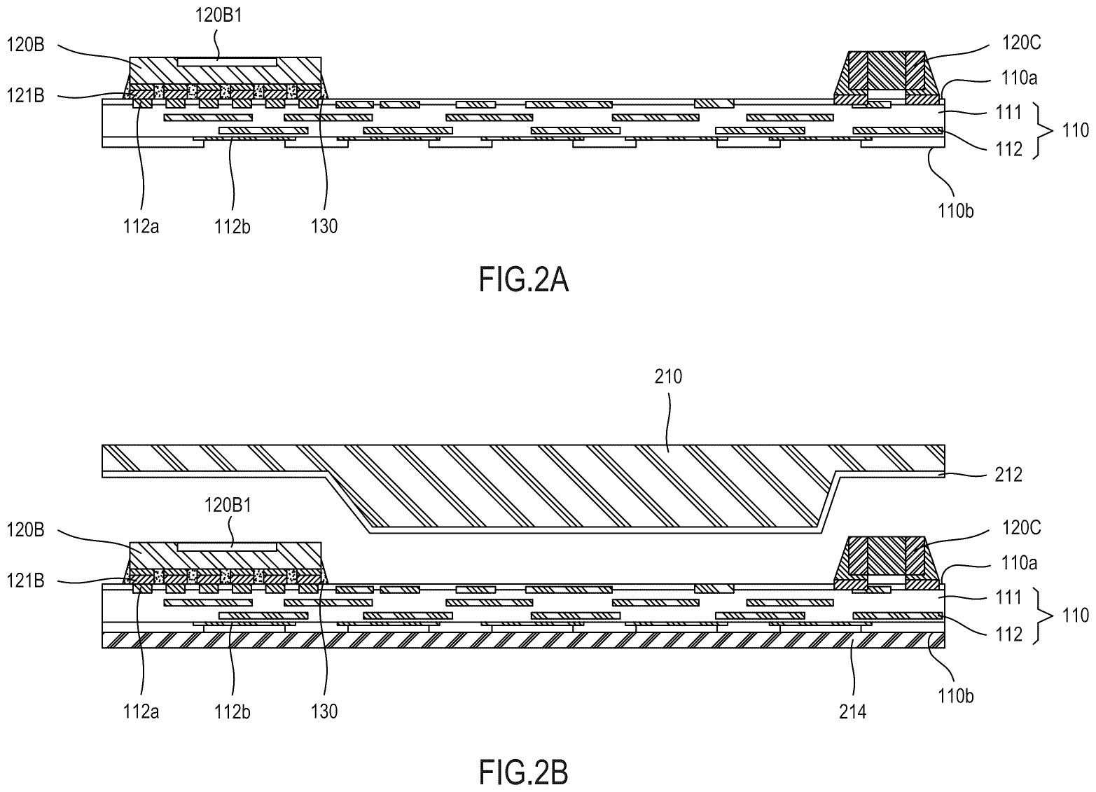

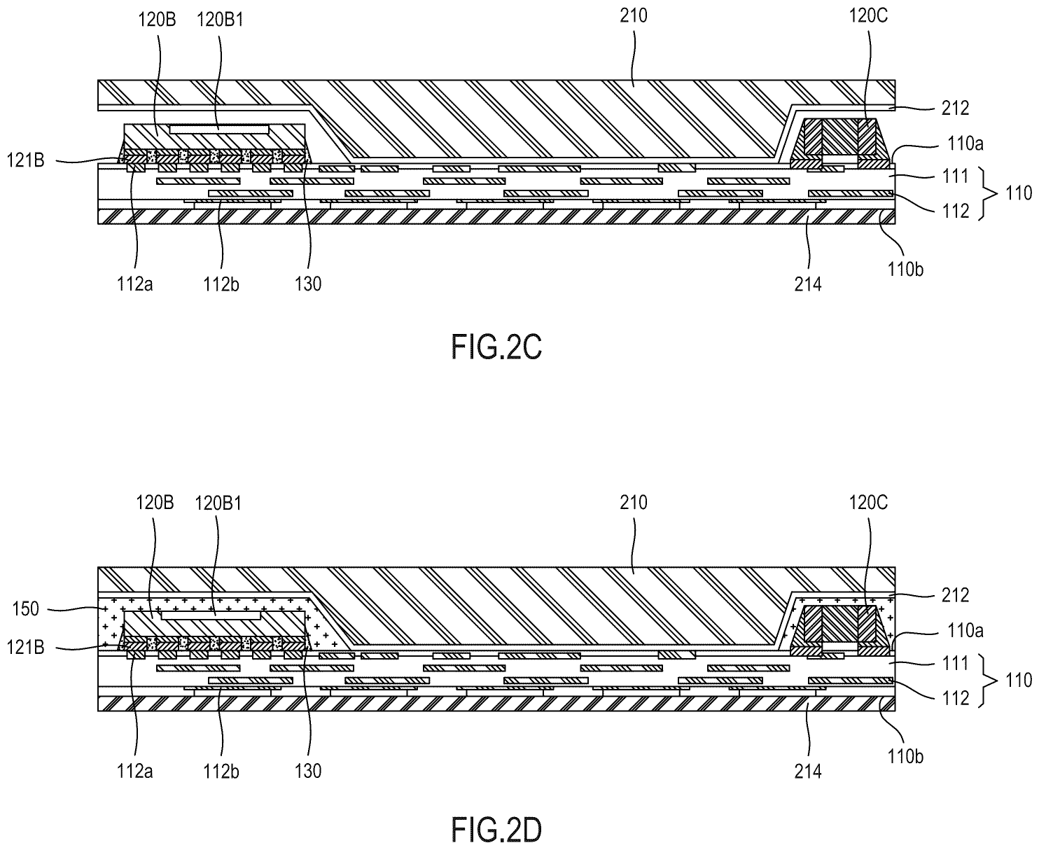

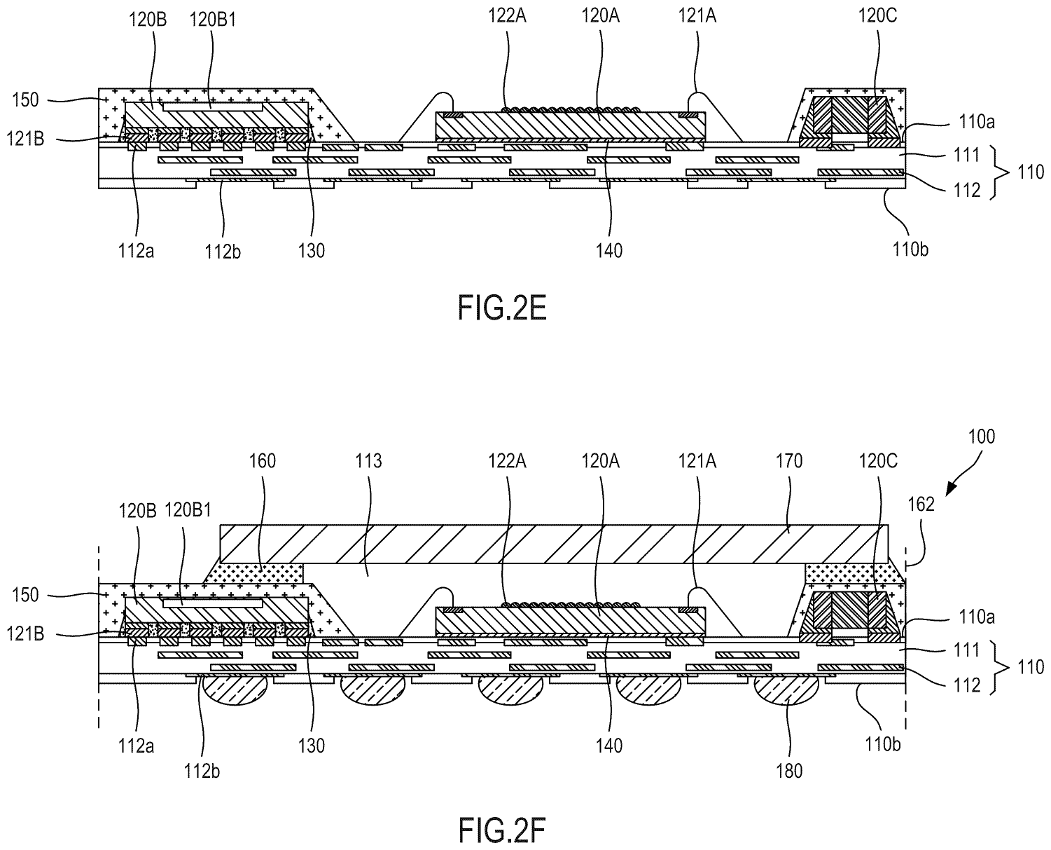

FIGS. 2A to 2F show cross-sectional views of an example method for manufacturing an example electronic device. FIG. 2A shows a cross-sectional view of electronic device 100 at an early stage of manufacture. In the example shown in FIG. 2A, electronic component 120B can be provided over top side 110a of substrate 110 and coupled to conductive structure 112. One or more component interconnects 121B can be coupled to substrate inward terminals 112a of conductive structure 112. Electronic component 120C can be coupled to conductive structure 112 at top side 110a of substrate 110. In some examples, electronic component 120B or electronic component 120C can comprise a semiconductor die, chip, package, active component, or passive component. A passive component can refer to an electronic component that generally does not require an external power source to operate or provide an intended function, and can include, for example, a resistor, capacitor, inductor, transformer, or antenna, among other examples. In contrast to a passive component, an active component can refer to an electronic component that can control an electrical current or an electrical voltage responsive to an applied electrical signal and that generally requires an external power source to operate or provide an intended function. An active component can include, for example, a transistor, amplifier, transmitter, receiver, transceiver, logic gate, or integrated circuit. In some examples, electronic component 120B can have transceiver 120B1 that can comprise a radar device or a radar sensor, and electronic component 120C can comprise a passive device.

In some examples, dielectric structure 111 of substrate 110 can comprise one or more dielectric layers of dielectric material interleaved with one or more layers or traces of conductive structure. In some examples, dielectric structure 111 can comprise any one or more of various materials, for example polyimide (PI), benzocyclobutene (BCB), polyphenylene benzobisoxazole (PBO), Ajinomoto build-up film (ABF), resin, mold, ceramic, glass, or silicon (Si). In some examples, conductive structure 112 can comprise one or more conductive layers or traces defining signal distribution elements, for example traces, vias, pads, conductive paths, or under bump metallization (UBM). In some examples, substrate inward terminals 112a can be located at top side 110a of substrate 110 and can comprise pads, lands, UBM, or studs. In some examples, substrate outward terminals 112b can be located at bottom side 110b of substrate 110 and can comprise pads, lands, or UBM. In some examples, component interconnects 121B can comprise flip chip interconnects such as bumps, pads, or pillars, and in other examples, component interconnects 121B can comprise wire bonds. Underfill 130 can be disposed between top side 110a of substrate 110 and electronic component 120B. Underfill 130 can cover the lateral sides of one or more of component interconnects 121B, the space between component interconnects 121B, or the space between top side 110a of substrate 110 and electronic component 120B. Underfill 130 can comprise capillary underfill (CUF), non-conductive paste (NCP), non-conductive film (NCF), or anisotropic conductive film (ACF).

In some examples, substrate 110 can be a redistribution layer (RDL) substrate. RDL substrates can comprise one or more conductive redistribution layers and one or more dielectric layers and (a) can be formed layer by layer over an electronic device to which the RDL substrate is to be coupled, or (b) can be formed layer by layer over a carrier and can be entirely removed or at least partially removed after the electronic device and the RDL substrate are coupled together. RDL substrates can be manufactured layer by layer as a wafer-level substrate on a round wafer in a wafer-level process, or as a panel-level substrate on a rectangular or square panel carrier in a panel-level process. RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, or (b) fan-in electrical traces within the footprint of the electronic device. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process and can include a photolithographic mask through where light is exposed to photo-pattern desired features such as vias in the dielectric layers. The dielectric layers can be made from photo-definable organic dielectric materials such as, for example, PI, BCB, or PBO. Such dielectric materials can be spun-on or otherwise coated in liquid form, as well as laminated as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of one or more inorganic dielectric layers can comprise silicon nitride (Si3N4), silicon oxide (SiO2), or silicon oxynitride (SiON). The one or more inorganic dielectric layers can be formed by growing the inorganic dielectric layers using an oxidation or nitridization process instead using photo-defined organic dielectric materials. Such inorganic dielectric layers can be filler-fee, without strands, weaves, or other dissimilar inorganic particles. In some examples, the RDL substrates can omit a permanent core structure or carrier such as, for example, a dielectric material comprising bismaleimide triazine (BT) or fiberglass-reinforced epoxy-laminated sheet such as FR4, and these types of RDL substrates can comprise or be referred to as a coreless substrate.

In some examples, substrate 110 can be a pre-formed substrate. Pre-formed substrates can be manufactured prior to attachment to an electronic device and can comprise dielectric layers between respective conductive layers. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or ABF. The pre-formed substrate can include a permanent core structure or carrier such as, for example, a dielectric material comprising BT or FR4, and dielectric and conductive layers can be formed on the permanent core structure. In other examples, the pre-formed substrate can be a coreless substrate and omits the permanent core structure, and the dielectric and conductive layers can be formed on a sacrificial carrier and is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process. Other substrates, as disclosed herein, can comprise RDL substrates or pre-formed substrate.

FIGS. 2B-2D show electronic device 100 at a later stage of manufacture. In the example shown in FIG. 2B, mold chase 210 can be placed over top side 110a of substrate 110. In some examples, carrier 214 can be provided under bottom side 110b of substrate 110. In some examples, carrier 214 can be separate from mold chase 210, and in other examples carrier 214 can be part of mold chase 210. Mold chase 210 can extend between electronic component 120B and electronic component 120C, and can be over the top sides of electronic component 120B and electronic component 120C. In some examples, a protective film 212 can be disposed on the bottom side of mold chase 210 to serve as a protective barrier between mold chase 210 and the mold compound or encapsulant at a later stage of manufacture. In the example shown in FIG. 2C, when mold chase 210 is in place, a sufficient amount of space is provided surrounding electronic component 120B and electronic component 120C to accommodate the mold compound or encapsulant. In the example shown in FIG. 2D, encapsulant 150 can be deposited between mold chase 210 and top side 110a of substrate to cover the lateral sides and the top sides of electronic component 120B and electronic component 120C. Encapsulant 150 can comprise epoxy molding compound (EMC), resin, filler reinforced polymer, B-stage pressed film, gel, and so on. Component interconnects 121B can be protected from contacting encapsulant 150 by underfill 130 such that the space between top side 110a of substrate 110 and the bottom side of electronic component 120B can be free of encapsulant. In other examples, encapsulant 150 can be disposed between top side 110a of substrate 110 and the bottom side of electronic component 120B in lieu of underfill material 130 as a molded underfill (MUF), and can contact the lateral sides of component interconnects 121B.

FIG. 2E shows electronic device 100 at a later stage of manufacture. In the example shown in FIG. 2E, mold chase 210 and protective film 212 can be removed to expose the top side of encapsulant 150. As a result of the shape of mold chase 210, a cavity 113 can be provided over top side 110a of substrate 100 and between electronic component 120B and electronic component 120C. Electronic component 120A can be placed over top side 110a of substrate 110 in cavity 113. In some examples, electronic component 120A can comprise an image sensor die having a transceiver 122A or image sensor or image sensing area disposed on the top side of electronic component 120A. In some examples, transceiver 122A can comprise an emitter, a receiver, or both. In some examples, transceiver 122A can operate using the principles of imaging, optics, radar, acoustics, surface acoustic wave (SAW) filters, multi-lens arrays (MLAs), or micro-electromechanical (MEMS) devices, and so on. Electronic component 120A can be coupled to conductive structure 112 of substrate 110 using one or more component interconnects 121A. In some examples, component interconnects 121A can comprise wires or wire bonds. Although component interconnects 121A are shown in FIG. 2E as wires, it is contemplated and understood that, in some examples, component interconnects 121A can comprise various other types of interconnects such as through-silicon vias (TSV) as one example. Electronic component 120A can be coupled to top side 110A of substrate 110 using die attach material 140 such as an adhesive, and epoxy, or a film.

FIG. 2F shows electronic device 100 at a later stage of manufacture. In the example shown in FIG. 2F, lid 170 can be placed over top side 110a of substrate 110 to cover electronic component 120A. In some examples, lid 170 can comprise a translucent material, a transparent material, or a material that is transmissive to the waveforms of operation utilized by transceiver 122A of electronic component 120A. For example, lid 170 can comprise glass and can be transmissive to visible light, infrared light, ultraviolet light, radio waves, or radar waves. In some examples, lid 170 may not be transmissive to visible light but otherwise can be transmissive to the wavelength of the electromagnetic waves employed by the technology of operation of transceiver 122A. In some examples, lid 170 can include or comprise a filter, a polarizer, a diffuser, or a lens. In some examples, lid 170 can have one or more optical properties, for example a refractive index, a reflective index, absorption, or scattering. In some examples, lid attach material 160 can be used to couple lid 170 to the top side of encapsulant 150. In some examples, lid attach material 160 can be used to hermetically seal electronic component 120A in cavity 130. Lid attach material 160 can comprise, for example, an adhesive, an epoxy, or a film. In some examples, lid 170 can be positioned to cover a portion of the top side of encapsulant 150 or the top side of electronic component 120B, and another portion of the top side of encapsulant 150 or the top side of electronic component 120B can be uncovered by lid 170. In some examples, a portion of electronic component 120B may not be vertically overlapped by lid 170. External interconnects 180 can be provided at bottom side 110b of substrate 110 and can be coupled to substrate outward terminals 112b. External interconnects 180 can comprise solder balls, bumps, pads, pillars, and so on. In some examples, external interconnects 180 can comprise a land grid array (LGA). In some examples, multiple electronic devices 100 are manufactured at the same time, for example as a panel or reconstituted wafer, and individual electronic devices 100 can be provided by singulating, for example by cutting or sawing, through encapsulant 150 and substrate 110 at singulation lines 162.

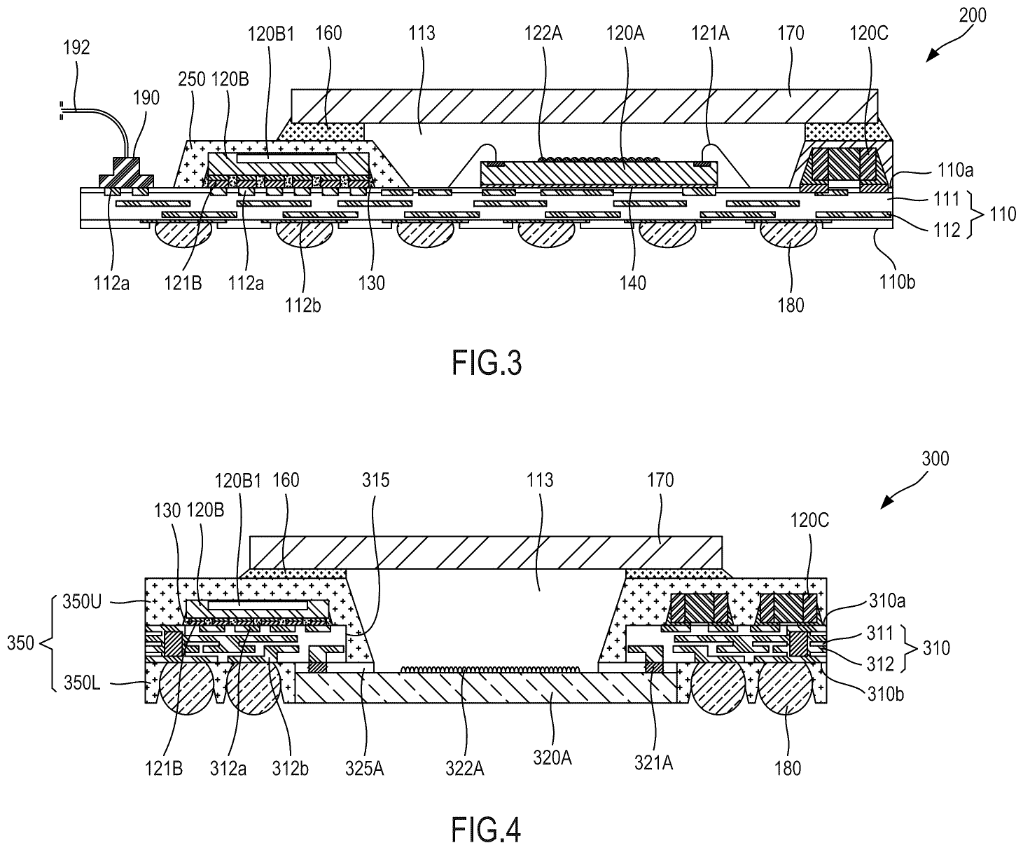

FIG. 3 shows a cross-sectional view of an example electronic device 200. In the example shown in FIG. 3, electronic device 200 can be substantially similar to electronic device 100 of FIG. 1 and can be manufactured using a similar process as shown in and described with respect to FIGS. 2A-2F, with differences as follows. A portion of top side 110a of substrate 110 can be exposed from encapsulant 250 near electronic component 120B at a lateral end of substrate 110. Encapsulant 250 can comprise the same or similar material as encapsulant 150 of FIG. 1. Connector 190 can be disposed over top side 110a of substrate 110 at the exposed region of substrate 110, and can be uncovered by lid 170. Connector 190 can be coupled to conductive structure 112 of substrate 110, for example at substrate inward terminals 112a. In some examples, connector 190 can comprise an antenna connector and can connect with or be in communication with antenna 192.

FIG. 4 shows a cross-sectional view of an example electronic device 300. In the example shown in FIG. 4, electronic device 300 can have the same, similar, or analogous structures as shown in and described with respect to FIG. 1 above. Electronic device 300 can comprise substrate 310 having substrate aperture hole, opening, or cavity 315. In some examples, substrate aperture 315 can be coincident with or at least partially coincident with cavity 113 of electronic device 300. In some examples, substrate 310 can be referred to as a cavity substrate. Substrate 310 can comprise dielectric structure 311 and conductive structure 312 and can have top side 310a and bottom side 310b opposite to top side 310a. Electronic component 320A can be disposed below bottom side 310b of substrate 310. Electronic component 320A can be coupled to bottom side 310b of substrate 310. Electronic component 320A can be the same as or similar to electronic component 120A of FIG. 1 and can include transceiver 322A on the top side of electronic component 320A and disposed in cavity 113 and substrate aperture 315. Substrate aperture 315 can be coincident with or located over transceiver 122A.

Transceiver 322A can be the same as or similar to transceiver 122A, as described above. In some examples, electronic component 320A can comprise a die, chip, package, or a passive component. In some examples, electronic component 320A can comprise an image sensor die. Electronic component 320A can comprise or be coupled to component interconnect 321A to couple electronic component 320A to conductive structure 312 of substrate 310. In some examples, component interconnect 321A can comprise a bump, pad, or pillar, and so on. Underfill 325A can be disposed between the top side of electronic component 320A and bottom side 310b of substrate and can cover a lateral side of component interconnect 321A. In some examples, encapsulant 350 can be provided to cover or encapsulate substrate 310 and can cover the lateral side of component interconnect 321A instead of underfill 325A.

In some examples, encapsulant 350 can be the same or similar to encapsulant 150 of FIG. 1 and can comprise epoxy molding compound (EMC), resin, filler reinforced polymer, B-stage pressed film, gel, and so on. In the example shown in FIG. 4, encapsulant 350 can comprise upper encapsulant portion 350U which can be over top side 310a of substrate 310 and can cover the lateral sides or the top side of electronic component 120B or electronic component 120C. In some examples, upper encapsulant portion 350U can be the same or similar to encapsulant 150 of FIG. 1. Upper encapsulant portion 350U can extend into substrate aperture 315 and can cover internal lateral sides of substrate 310. In some examples, upper encapsulant portion 350U can cover the top side of electronic component 320A in substrate aperture 315 while leaving transceiver 322A uncovered by upper encapsulant portion 350U. Lid 170 can be over cavity 113 and can be coupled to upper encapsulant portion 350U, for example with lid attach material 160.

In some examples, electronic component 120B can be coupled to conductive structure 312 of substrate 310. For example, component interconnects 121B can be coupled between electronic component 120B and substrate inward terminals 312a. Underfill material 130 can be disposed between top side 310a of substrate 310 and the bottom side of electronic component 120B. In some examples, underfill material 130 can protect component interconnects 121B from upper encapsulant portion 350U. In other examples, upper encapsulant portion 350U can be disposed between top side 310a of substrate 310 and the bottom side of electronic component 120B in lieu of underfill material 130 as a molded underfill (MUF), and can contact the lateral sides of component interconnects 121B. Lower encapsulant portion 350L can cover bottom side 310b of substrate 310 and can cover the lateral side of electronic component 320A. Electronic component 320A can be exposed from lower encapsulant portion 350L. In some examples, upper encapsulant portion 350U can be applied concurrently with lower encapsulant portion 350L as part of the same molding operation. In other examples, upper encapsulant portion 350U can be applied sequentially with lower encapsulant portion 350L as part of different molding operations, with either upper encapsulant portion 350U being applied first and then lower encapsulant portion 350L being applied, or vice versa.

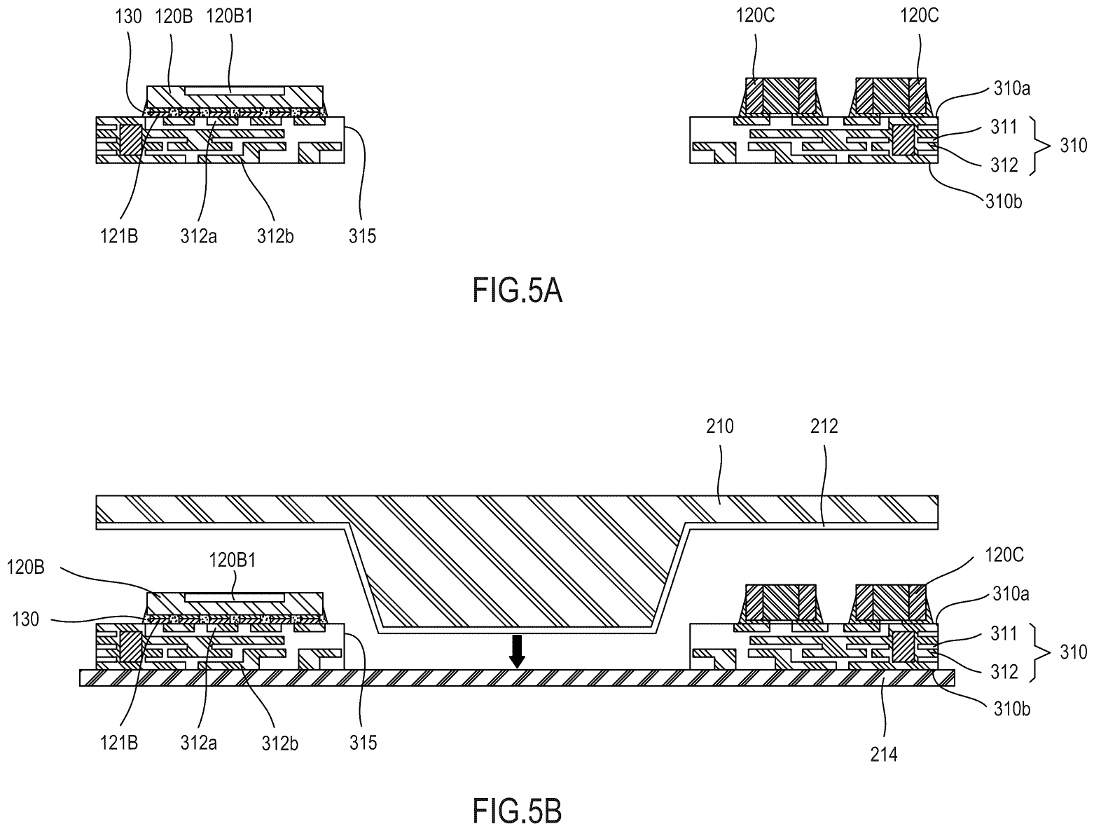

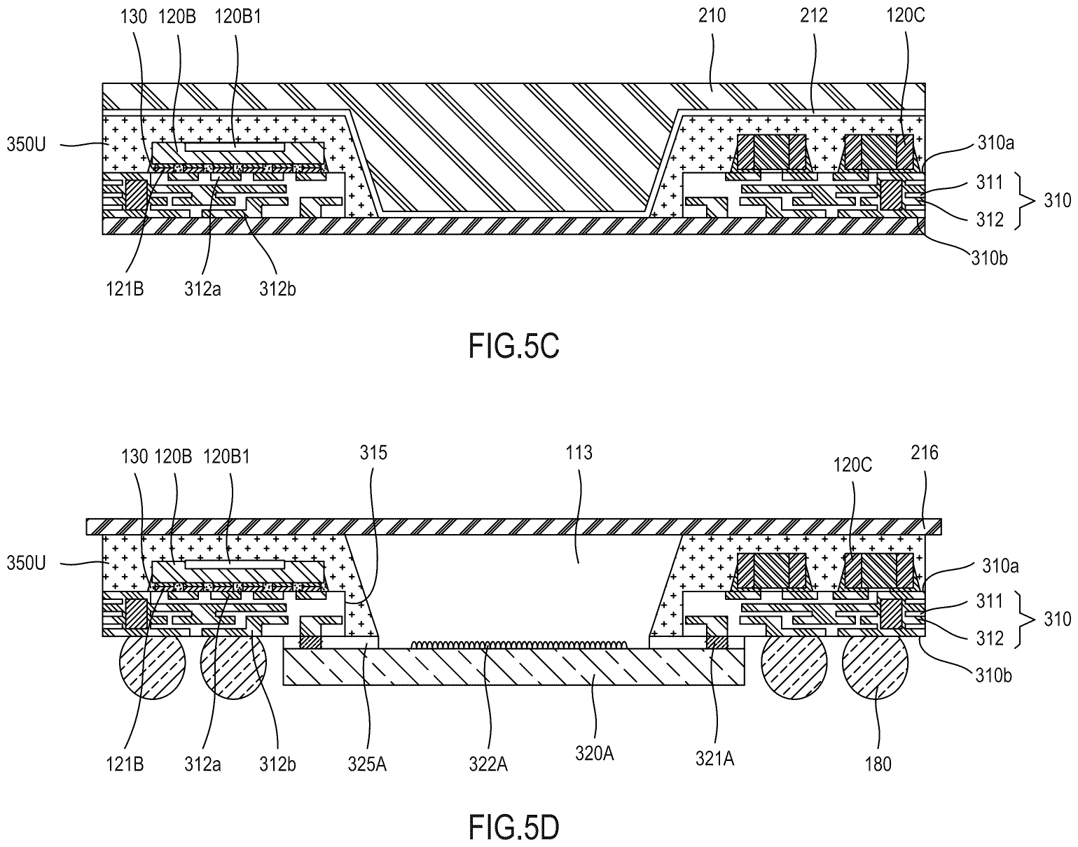

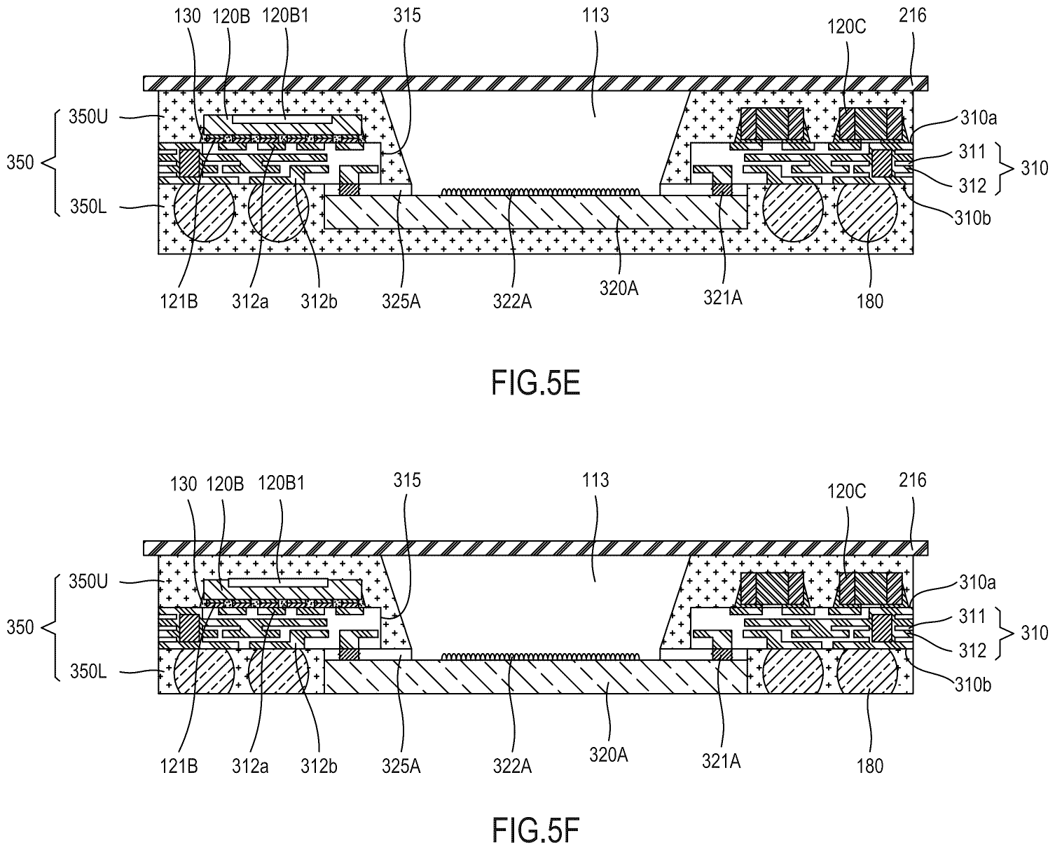

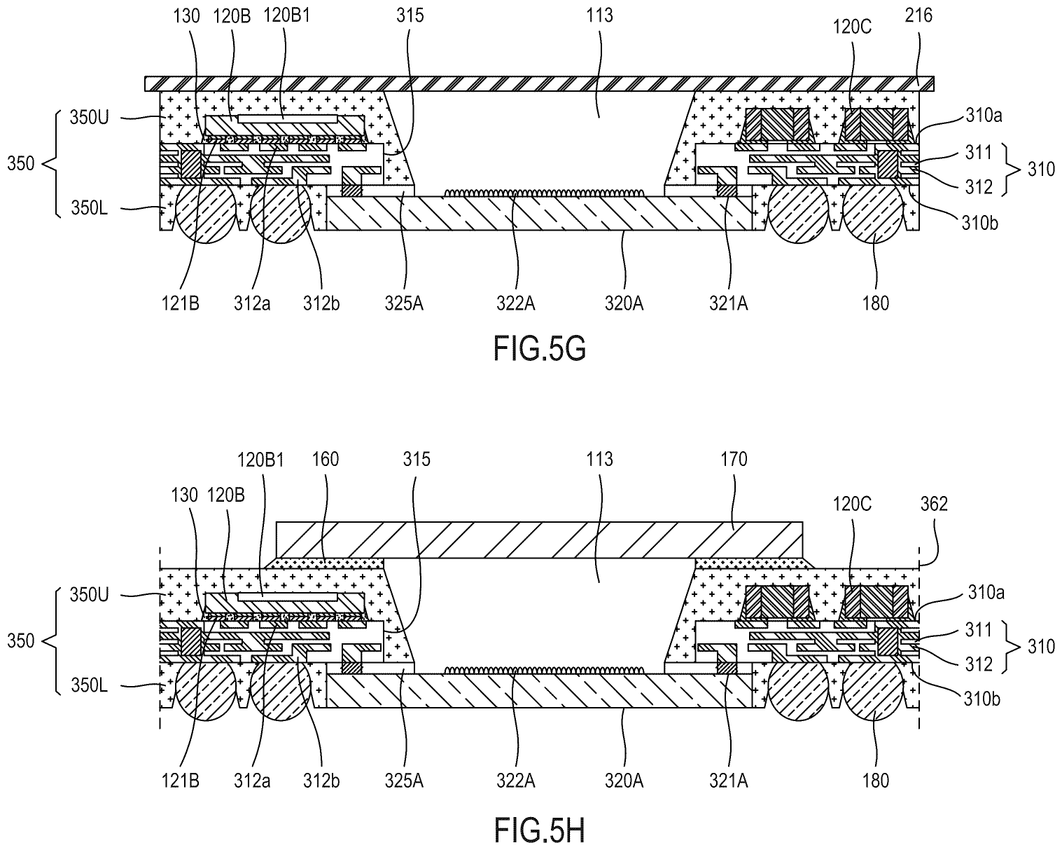

FIGS. 5A to 5H show cross-sectional views of an example method for manufacturing an example electronic device, such as electronic device 300 in FIG. 4. The manufacturing method shown in FIGS. 5A to 5H can be substantially similar to or analogous to the manufacturing method shown in and described with respect to FIGS. 2A to 2F with the following differences as discussed herein below. FIG. 5A shows a cross-sectional view of electronic device 300 at an early stage of manufacture. In the example shown in FIG. 5A, substrate 310 can be provided and can comprise top side 310a, bottom side 310b, dielectric structure 311, conductive structure 312, and substrate aperture 315. Conductive structure 312 can comprise substrate inward terminals 312a at top side 310a of substrate 310 and substrate outward terminals 312b at bottom side 310b of substrate 310. Electronic component 120B or one or more electronic components 120C can be provided over top side 310a of substrate 310 and can be coupled to conductive structure 312. In some examples, electronic component 120B can be coupled to conductive structure 312. For example, component interconnects 121B can be coupled to substrate inward terminals 312a. In some examples, underfill material 130 can be provided between top side 310a of substrate 310 and the bottom side of electronic component 120B and can cover the lateral sides of component interconnects 121B. Electronic components 120C can also be coupled to conductive structure 312.

FIGS. 5B-5C show electronic device 300 at a later stage of manufacture. In the example shown in FIG. 5B, mold chase 210 can be placed over top side 310a of substrate 310. Carrier 214 can be provided under bottom side 310b of substrate 310 to provide a structure at the bottom of substrate aperture 315. In some examples, carrier 214 can be separate from mold chase 210, and in other examples carrier 214 can be part of mold chase 210. Mold chase 210 can extend into substrate aperture 315 between electronic component 120B and electronic components 120C, and can be over the top sides of electronic component 120B and electronic component 120C. In some examples, a protective film 212 can be disposed on the bottom side of mold chase 210 to serve as a protective barrier between mold chase 210 and the mold compound or encapsulant at a later stage of manufacture. In the example shown in FIG. 5C, when mold chase 210 is in place, a sufficient amount of space is provided surrounding electronic component 120B and electronic component 120C to accommodate the mold compound or encapsulant. Encapsulant 350 can be deposited between mold chase 210 and top side 310a of substrate 310 to cover the lateral sides and the top sides of electronic component 120B and electronic components 120C. Encapsulant 350 can comprise epoxy molding compound (EMC), resin, filler reinforced polymer, B-stage pressed film, gel, and so on. In the example shown in FIG. 5C, encapsulant 350 can comprise upper encapsulant portion 350U.

Component interconnects 121B can be protected from contacting upper encapsulant portion 350U by underfill 130 such that the space between top side 310a of substrate 310 and the bottom side of electronic component 120B can be free of encapsulant 350U. In other examples, upper encapsulant portion 350U can be disposed between top side 310a of substrate 310 and the bottom side of electronic component 120B in lieu of underfill material 130 as a molded underfill (MUF), and can contact the lateral sides of component interconnects 121B. Carrier 214 can be removed from bottom side 310b of substrate 310 after encapsulant 350U has been applied to top side 310a of substrate 310.

FIG. 5D shows electronic device 300 at a later stage of manufacture. In the example shown in FIG. 5D, mold chase 210, protective film 212, and carrier 214 can be removed from substrate 310, and carrier 216 can be positioned on the top side of upper encapsulant portion 350U and over substrate aperture 315 and cavity 113. Electronic component 320A can be provided at bottom side 310b of substrate 310 with transceiver 322A positioned in substrate aperture 315 and cavity 113. Electronic component 320A can be coupled to conductive structure 312 using component interconnects 321A. In some examples, underfill material 325A can be provided between bottom side 310b of substrate 310 and the top side of electronic component 320A and can cover a lateral side of component interconnect 321A. External interconnects 180 can be provided at bottom side 310b of substrate 310 and can be coupled to conductive structure 312, for example, to substrate outward terminals 312b.

FIG. 5E-5G show electronic device 300 at a later stage of manufacture. In the example shown in FIG. 5E, lower encapsulant portion 350L can be provided at bottom side 310b of substrate 130 and can cover the lateral sides or the bottom side of electronic component 320A and can cover external interconnects 180. In the example shown in FIG. 5E, lower encapsulant portion 350L can be grinded along with a portion of external interconnects 180. In some examples, a portion of the bottom side of electronic component 320A can also be removed during the grinding process as shown in FIG. 5F. Grinding of lower encapsulant portion 350L can expose the bottom side of electronic component 320A from lower encapsulant portion 350L and the bottom side of external interconnects 180. In some examples, underfill material 325A can be eliminated and lower encapsulant portion 350L can be provided between bottom side 310b of substrate 310 and the top side of electronic component 320A and can cover a lateral side of component interconnect 321A.

In the example shown in FIG. 5G, external interconnects 180 can be reflowed. In response to the reflowing of external interconnects 180, a portion of external interconnects 180 can extend below the bottom side of lower encapsulant portion 350L. In some examples, after reflow, there can be a space between a lower portion of the lateral side of external interconnects 180 and lower encapsulant portion 350L.

FIG. 5H shows electronic device 300 at a later stage of manufacture. In the example shown in FIG. 5H, carrier 216 can be removed and lid 170 can be provided over substrate aperture 315 and over the top side of upper encapsulant portion 350U to cover the top side of electronic component 320A including transceiver 322A. Lid 170 can be attached to encapsulant upper portion 350U using lid attach material 160. In some examples, lid attach material 160 can hermetically seal cavity 113. In some examples, lid 170 can cover a portion of the top side of upper encapsulant portion 350U or the top side of electronic component 120B or electronic components 120C, and another portion of the top side of upper encapsulant portion 350U or the top side of electronic component 120B or electronic components 120C can be uncovered by lid 170. In some examples, multiple electronic devices 300 are manufactured at the same time, for example as a panel or reconstituted wafer, and individual electronic devices 300 can be singulated by cutting or sawing through encapsulant 350 and substrate 310 at singulation lines 362.

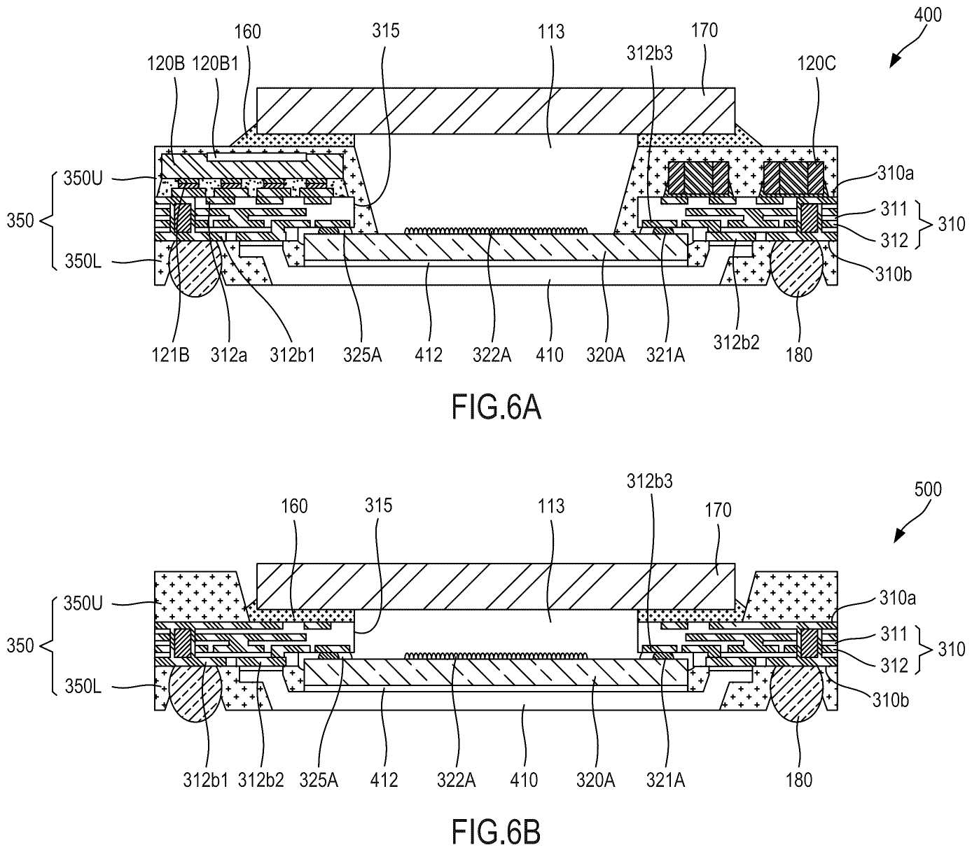

FIGS. 6A to 6B show cross-sectional views of example electronic devices 400 and 500, respectively. Example electronic device 400 of FIG. 6A and example electronic device 500 of FIG. 6B can be substantially similar to electronic device 300 of FIG. 4 and can be manufactured in substantially the same or similar process as shown in and described with respect to FIGS. 5A to 5H with the following differences as discussed below. In the example shown in FIG. 6A, electronic device 400 can include heat spreader 410. Heat spreader 410 can be provided below bottom side 310b of substrate 310 and below the bottom side of electronic component 320A. Heat spreader 410 can be coupled to bottom side 310b of substrate 310. Heat spreader 410 can cover the bottom side of electronic component 320A. Heat spreader 410 can be exposed from the bottom side of lower encapsulant portion 350L. Heat spreader 410 can be coupled to electronic component 320A or bottom side 310b of substrate 310 using attach material 412. In some examples, attach material 412 can comprise a thermally conductive adhesive or similar material to facilitate the transfer of heat from electronic component 320 to heat spreader 410 and external to electronic device 400. In some examples, attach material 412 can comprise an electrically conductive material.

In the example shown in FIG. 6A, lid 170 can be over the top side of encapsulant upper portion 350U and over electronic component 320A, and can be coupled to upper encapsulant portion 350U using lid attach material 160. In the arrangement of FIG. 6A, lid 170 is over the top side of upper encapsulant portion 350U and over the top sides of electronic component 120B or electronic components 120C similar to the arrangement of lid 170 as shown in FIG. 4. In some examples, one or more electronic components can be over top side 310a of substrate 310 and can be covered by encapsulant 350 such as upper encapsulant portion 350U. In the example shown in FIG. 6B, electronic device 500 is substantially similar to electronic device 400 of FIG. 6A except that a portion of top side 310a of substrate 310 is exposed from and uncovered by upper encapsulant portion 350U which allows lid 170 to be coupled to top side 310a of substrate 310 at the exposed portion of substrate 310. In such an arrangement, at least a portion of lid 170 can be lower than the top side of upper encapsulant portion 350U, and lid 170 can be coupled to top side 310a of substrate 310 instead of being coupled to the top side of upper encapsulant portion 350U. Lid 170 can be coupled to top side 310a of substrate using lid attach material 160. In some examples, lid attach material 160 can hermetically seal cavity 113. In some examples, upper encapsulant portion 350U disposed over top side 310a of substrate 310 can be adjacent the lateral side of lid 170, and in some examples top side 310a of substrate 310 and upper encapsulant portion 350U can be free of any electronic components such as electronic component 120B or electronic components 120C.

In some examples, electronic component 320A can be coupled to a recessed portion of bottom side 310b of substrate 310. For example, component interconnect 321A can be coupled to terminal 312b3 of conductive structure 312 at the recessed portion of bottom side 310b of substrate 310. Underfill 325A can be between electronic component 320A and bottom side 310b of substrate 310 and can cover component interconnect 321A. External interconnects 180 can be coupled to terminal 312b1 of conductive structure 312 at the recessed portion of bottom side 310b of substrate 310. Heat spreader 410 can be coupled to terminal 312b2 of conductive structure 312 312 at the recessed portion of bottom side 310b of substrate 310. In some examples, electronic component 320A can be coupled at the recessed portion of bottom side 310b of substrate 310 such that the bottom side of terminal 312b3 can be recessed, at a different horizontal plane, relative to the horizontal plane of terminal 312b1 or terminal 312b2. In some examples, there is no recessed portion at bottom side 310b of substrate 310 where electronic component is coupled with bottom side 31b of substrate 310. In such examples, the bottom sides of terminal 312b1, terminal 312b2, and terminal 312b3 can be substantially coplanar.

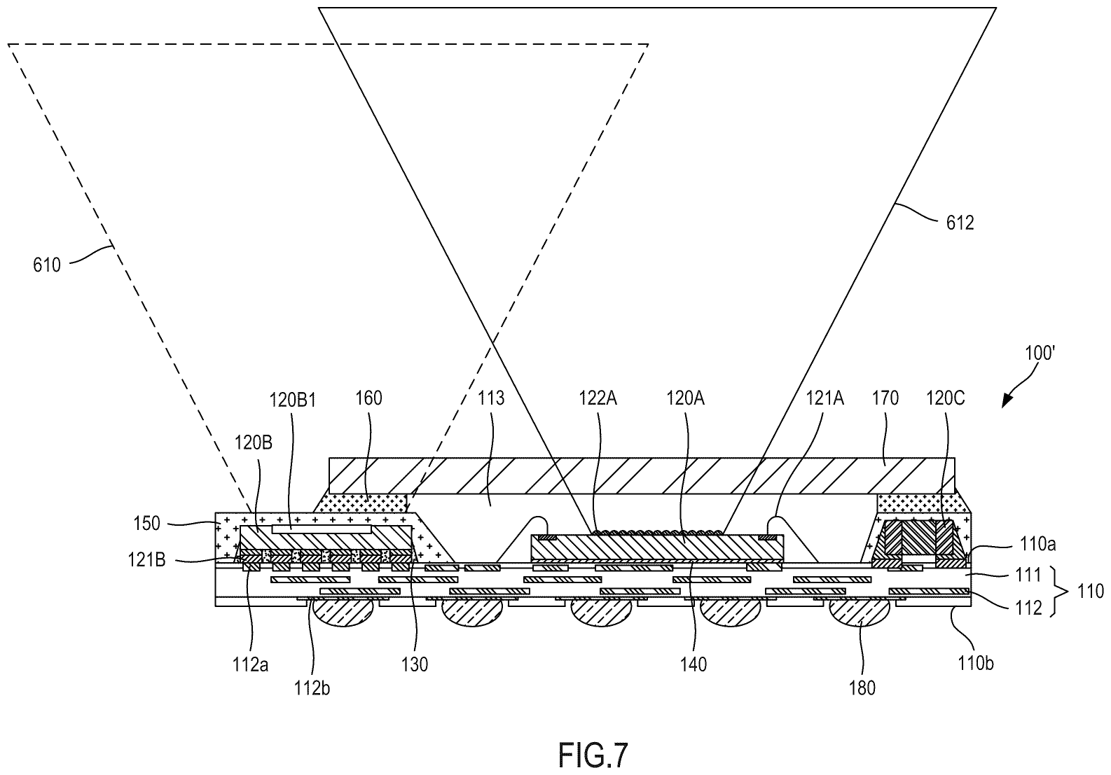

FIG. 7 shows a cross-sectional view of an example electronic device 100′. In the example shown in FIG. 7, electronic device 100′ is shown as having two or more electronic components such as electronic component 120B and electronic component 120A over top side 110a of substrate 110. Electronic component 120B can be laterally offset from electronic component 120A such that field of view 610 of electronic component 120B can be offset from field of view 612 of electronic component 120A. For example, electronic component 120B can have transceiver 120B1 that can comprise a radar device and accompanying antennas having a radar field of view 610, and electronic component 120A can comprise an imaging device including a transceiver comprising an imager 122A having an imaging field of view 612. In some examples, field of view 612 can be through lid 170. In general, the term “field of view” can refer to a field of view of an electronic component such as electronic component 120B or electronic component 120A, and is not necessarily attributed to any specific element of a given electronic component. In some examples, electronic component 120B can include one or more antennas that can be coupled with or in communication with transceiver 120B1, and the one or more antennas can be disposed in, on, or near electronic component 120B. For example, electronic component 120B could comprise transceiver 120B1 and a substrate to which transceiver 120B1 is coupled, and the one or more antennas could be formed in the substrate or coupled to the substrate. In some examples, the one or more antennas can be disposed in, on, or near encapsulant 150 or substrate 110. In some examples, field of view 610 can be through encapsulant 150 and/or through lid 170. In general, field of view can refer to an image detection region, a signal detection region, or a sensing region, and the scope of the present disclosure is not limited in these respects. In some examples, field of view 610 can at least partially overlap field of view 612. In some examples, field of view 610 or field of view 612, or a combination thereof, can have one or more different shapes or sizes based on a selected mode of operation of the respective electronic component, for example a wide field of view, a medium field of view, or a narrow field of view. In an arrangement of spaced apart sensors, each of electronic component 120B and electronic component 120A can have a different perspective on the external environment where electronic device 100 is deployed due to parallax. For example, electronic device 100′ can be deployed in a motor vehicle as sensors that assist in the operation or driving of the motor vehicle. The offset fields of view can facilitate detection of objects in the external environment. For example, where an object is occluded in one field of view but not occluded in the other field of view, the object can still be detected by the sensor whose field of view is not occluded. Such an arrangement is one example application of electronic device 100′ having two or more offset sensors having offset fields of view, and the scope of the disclosed subject matter is not limited in this respect.

The present disclosure includes reference to certain examples. It will be understood by those skilled in the art, however, that various changes may be made and equivalents may be substituted without departing from the scope of the disclosure. In addition, modifications may be made to the disclosed examples without departing from the scope of the present disclosure. Therefore, it is intended that the present disclosure is not limited to the examples disclosed, but that the disclosure will include all examples falling within the scope of the appended claims.

1. An electronic device, comprising:
a substrate comprising a dielectric structure and a conductive structure;
a first electronic component over a top side of the substrate and comprising a first transceiver, wherein the first electronic component is coupled to the conductive structure;
a second electronic component coupled to the substrate and the conductive structure and comprising a second transceiver;
an encapsulant over the top side of the substrate and defining a cavity, wherein the second transceiver is in the cavity and the first electronic component is covered by the encapsulant; and
a lid over the top side of the substrate and covering the second electronic component.

2. The electronic device of claim 1, wherein:
the first electronic component has a first field of view;
the second transceiver is at a top side of the second electronic component, and the second electronic component has a second field of view through the lid; and
the first field of view is offset from the second field of view, and the first field of view at least partially overlaps the second field of view.

3. The electronic device of claim 1, wherein:
the first transceiver comprises a radar sensor; and
the second transceiver comprises an image sensor.

4. The electronic device of claim 1, wherein:
the second electronic component is over the top side of the substrate.

5. The electronic device of claim 1, wherein:
the second electronic component is coupled to a bottom side of the substrate.

6. The electronic device of claim 5, comprising:
a heat spreader coupled to the bottom side of the substrate.

7. The electronic device of claim 1, comprising:
a third electronic component over the top side of the substrate;
wherein the third electronic component is covered by the encapsulant.

8. An electronic device, comprising:
a substrate comprising a dielectric structure and a conductive structure;
a first electronic component coupled to the substrate and the conductive structure and comprising a first transceiver;
a second electronic component coupled to the substrate and the conductive structure and comprising a second transceiver;
an encapsulant over the substrate and the first electronic component and defining a cavity, wherein the cavity is coincident with the second transceiver; and
a lid over the second electronic component.

9. The electronic device of claim 8, wherein:
the substrate comprises a substrate aperture located over the second transceiver.

10. The electronic device of claim 8, wherein the encapsulant comprises:
an upper encapsulant portion over a top side of the substrate; and
a lower encapsulant portion below a bottom side of the substrate and covering a lateral side of the second electronic component.

11. The electronic device of claim 10, wherein:
the second electronic component is exposed from the lower encapsulant portion.

12. The electronic device of claim 10, wherein:
the lid is over the cavity and coupled to the upper encapsulant portion.

13. The electronic device of claim 10, comprising:
a heat spreader coupled to the bottom side of the substrate and covering a bottom side of the second electronic component;
wherein the heat spreader is exposed from the lower encapsulant portion.

14. The electronic device of claim 8, wherein:
a portion of the substrate is exposed from the encapsulant at a top side of the substrate; and
the lid is coupled to the portion of the substrate that is exposed from the encapsulant.

15. The electronic device of claim 8, wherein:
the first electronic component has a first field of view;
the second electronic component has a second field of view through the lid; and
the first field of view is offset from the second field of view, and the first field of view at least partially overlaps the second field of view.

16. The electronic device of claim 8, comprising:
a third electronic component over a top side of the substrate and coupled to the conductive structure;
wherein the third electronic component is covered by the encapsulant.

17. A method to manufacture an electronic device, comprising:
providing a substrate comprising a dielectric structure and a conductive structure;
providing a first electronic component over a top side of the substrate and comprising a first transceiver, wherein the first electronic component is coupled to the conductive structure;
providing an encapsulant over the top side of the substrate and defining a cavity, wherein the first electronic component is covered by the encapsulant;
providing a second electronic component coupled to the conductive structure in the cavity and comprising a second transceiver; and
providing a lid over the top side of the substrate and covering the second electronic component.

18. The method of claim 17, wherein:
the first electronic component has a first field of view;
the second transceiver is at a top side of the first electronic component, and the second electronic component has a second field of view through the lid; and
the first field of view is offset from the second field of view, and the first field of view at least partially overlaps the second field of view.

19. The method of claim 17, wherein:
the first transceiver comprises a radar sensor; and
the second transceiver comprises an image sensor.

20. The method of claim 17, wherein:
the second electronic component is over the top side of the substrate.
